(19) United States
(12) Patent Application Publication
(10) Pub. No.: US 2008/0023816 A1
(43) Pub. Date: Jan. 31, 2008

(54) Semiconductor package

(76) Inventors: Gwo-Liang Weng, Kao-Hsiung City (TW); Cheng-Yin Lee, Tai-Nan City (TW)

Correspondence Address: NORTH AMERICA INTELLECTUAL PROPERTY CORPORATION, P.O. BOX 506, MERRIFIELD, VA, 22116, US

(21) Appl. No.: 11/744,189

(22) Filed: May 3, 2007

(30) Foreign Application Priority Data
Jul. 28, 2006 (TW) 095127887

(51) Int. Cl. H01L 23/48

(52) U.S. Cl. 257/690; 257/E23.01

(57) ABSTRACT

A semiconductor package mainly includes a carrier, a package having a first surface and a second surface, a chip and a plurality of bonding wires. The package is disposed on an upper surface of the carrier and electrically connected to the carrier by a plurality of conductive elements, the chip is disposed on the second surface of the package, a plurality of pads of the chip are corresponding to an opening of the carrier, and the bonding pads of the chip are electrically connected to a plurality of conductive pads of the carrier by the bonding wires to lower the height of the semiconductor package and increase the space for circuit layout.

### BACKGROUND OF THE INVENTION

1. Field of the Invention

The present invention relates a semiconductor package and a method for manufacturing the same, and particularly, to a semiconductor package with a low package thickness.

2. Description of the Prior Art

In accordance with the progress of electronic technology, multi-functional electronic products become more and more popular in the consumption market. Due to the demand for lighter, smaller, and thinner products with multi-function, a multi-chip stacked package is developed.

As shown in FIG. 1, a conventional semiconductor package 100 includes a first package 110, a second package 120, and a carrier plate 130. The first package 110 includes a first substrate 111, a first chip 112, a plurality of bumps 113, and a plurality of first solder balls 114. The second package 120 includes a second substrate 121, a second chip 122, a plurality of second bumps 123, and a plurality of second solder balls 124. The first chip 112 is flip-chip bonded to the first substrate 111 through the first bumps 113, the second chip 122 is flip-chip bonded to the second substrate 121 through the second bumps 123, and one surface 125 of the substrate 121 of the second package 120 is provided with a plurality of solder balls 140 for electrically connecting to an external circuit board (not shown). To improve the product function, the first package 110 and the second package 120 must be stacked and the first package 110 should be electrically connected to the second package 120 through the carrier plate 130, the first solder balls 114, and the second solder balls 124. However, in the semiconductor package 100, a space between the first package 110 and the second package 120 must be retained for the deposition of the carrier plate 130, the first solder balls 114, and the second solder balls 124, such that the thickness of the semiconductor package 100 is large.

### SUMMARY OF THE INVENTION

A main objective of the present invention is to provide a semiconductor package and a method for manufacturing the same, in which a package having a first surface and a second surface is disposed on an upper surface of a carrier and electrically connected to the carrier, and a chip is disposed on the second surface of the package and electrically connected to the package. Since the chip is adhered to the package without the need to dispose an additional substrate for carrying the chip, the total thickness of the semiconductor package is reduced.

The semiconductor package according to the present invention comprises a carrier, a package, a chip, and a plurality of bonding wires. The carrier has an upper surface, a lower surface, an opening penetrating the upper surface and the lower surface, and a plurality of conductive pads disposed on the lower surface. The package is disposed on the upper surface of the carrier. The package has a first surface, a second surface, and a plurality of conductive elements. The package is electrically connected to the carrier through the conductive elements. The chip is disposed on the second surface of the package. The chip has an active surface and a plurality of bonding pads. The active surface faces to the carrier. The bonding pads are corresponding to the opening of the carrier. The bonding wires connect the bonding pads and the conductive pads.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic cross-sectional diagram illustrating a conventional semiconductor package;

FIG. 2 is a schematic cross-sectional diagram illustrating a semiconductor package according to the first embodiment of the present invention;

FIGS. 3A to 3E are schematic cross-sectional diagrams illustrating the semiconductor package during a manufacturing process according to the first embodiment of the present invention;

FIG. 4 is a schematic cross-sectional diagram illustrating a semiconductor package according to the second embodiment of the present invention; and

FIGS. 5A to 5D are schematic cross-sectional diagrams illustrating the semiconductor package during a manufacturing process according to the second embodiment of the present invention.

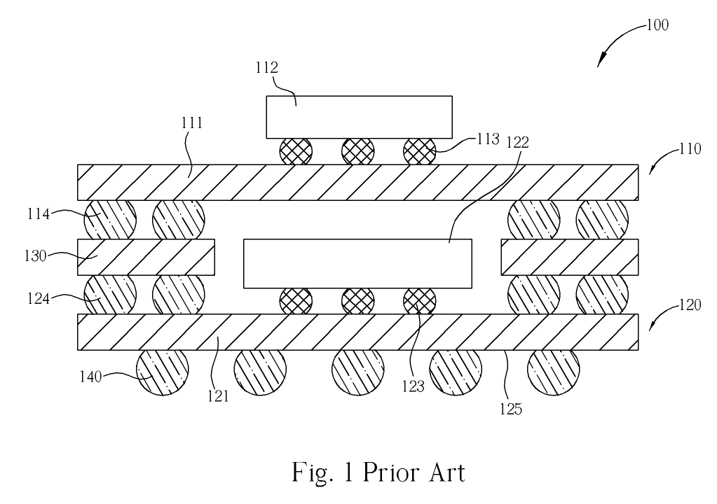

### DETAILED DESCRIPTION

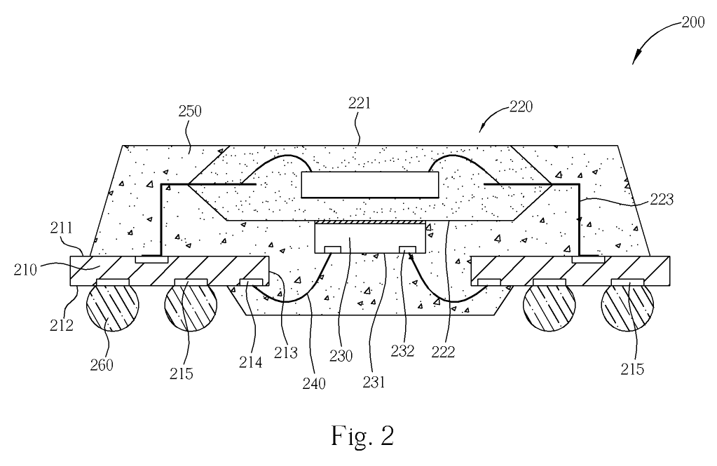

Please refer to FIG. 2, illustrating a semiconductor package 200 disclosed in the first embodiment according to the present invention. The semiconductor package 200 at least comprises a carrier 210, a package 220, a chip 230, and a plurality of bonding wires 240. The carrier 210 has an upper surface 211, a lower surface 212, an opening 213 penetrating the upper surface 211 and the lower surface 212, and a plurality of conductive pads 214 disposed on the lower surface 212. The package 220 is disposed on the upper surface 211 of the carrier 210 and electrically connected to the carrier 210. The package 220 has a first surface 221, a second surface 222, and a plurality of conductive elements 223. The package 220 may be a substrate type package or a leadframe type package, such as a BGA (Ball Grid Array) package or a TSOP (Thin Small Outline Package). In this embodiment, the package 220 has a structure of TSOP. The conductive elements 223 may be outer leads of a leadframe. The package 220 is electrically connected to the carrier 210 through the conductive elements 223. The chip 230 is disposed on the second surface 222 of the package 220. In this embodiment, the chip 230 is adhered to the second surface 222 of the package 220 through an adhesive. The chip 230 may be a memory chip, microprocesser, logic chip, or other chip such as DRAM, SRAM, SDRAM, ROM, EPROM, flash, Rambus or DDR memory chip. As shown in FIG. 2, the chip 230 has an active surface 231 and a plurality of bonding pads 232 on the active surface 231. The active surface 231 of the chip 230 faces to the carrier 210. The bonding pads 232 are corresponding to the opening 213 of the carrier 210. The bonding wires 240 connect the bonding pads 232 of the chip 230 and the conductive pads 214 on the lower surface 212 of the carrier 210, for electrically connecting the chip 230 and the carrier 210. Since the chip 230 is adhered to the second surface of the package 220, there is no need to further provide a substrate for carrying the chip 230. Accordingly, the height of the semiconductor package can be reduced. Furthermore, since the package 220 is disposed on the upper surface 211 of the carrier 210 and the chip 230 is electrically connected to the conductive pads 214 on the lower surface 212 of the carrier 210 through the bonding wires 240, the space for the circuit layout on the upper surface 211 and the lower surface 212 of the carrier 210 becomes relatively capacious. The semiconductor package 200 may further comprise a molding compound 250 sealing the package 220, the chip 230, and the bonding wires 240. The molding compound 250 may expose the first surface 221 of the package 220. The semiconductor package 200 may further comprise a plurality of solder balls 260 disposed on the lower surface 212 of the carrier 210, for connecting to an external circuit board (not shown). In this embodiment, a plurality of solder ball pads 215 are formed on the lower surface 212 of the carrier 210 for bonding the solder balls 260.

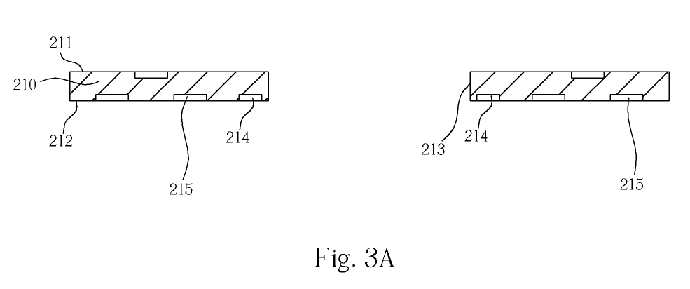

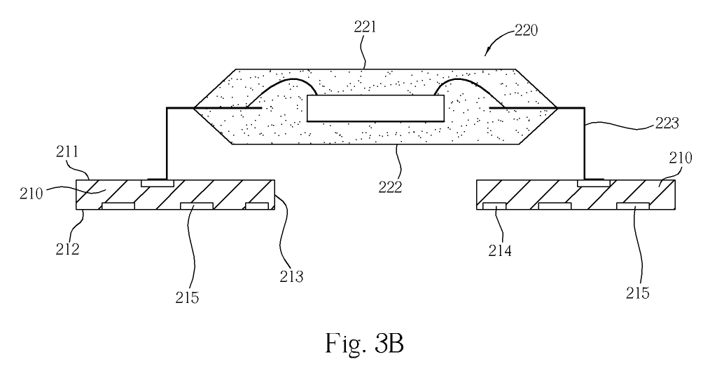

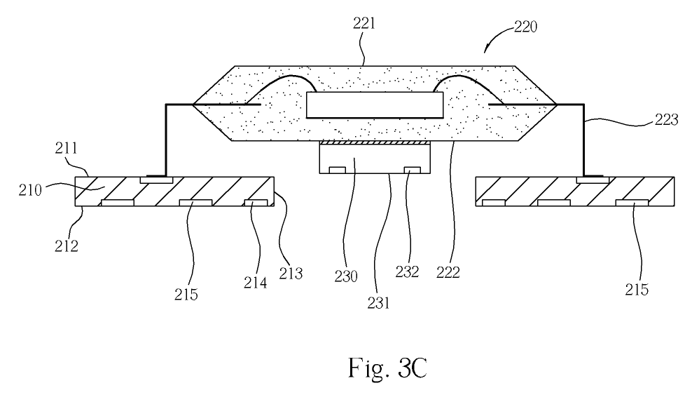

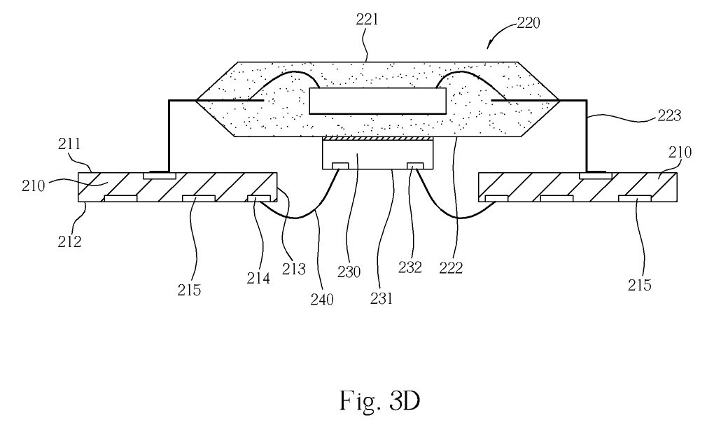

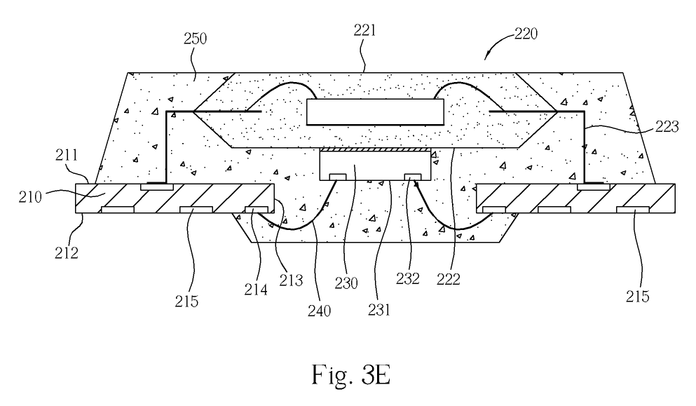

Please refer to FIGS. 3A to 3E illustrating the manufacturing process for the semiconductor package 200. First, referring to FIG. 3A, a carrier 210 is provided. The carrier 210 has an upper surface 211, a lower surface 212, an opening 213 penetrating the upper surface 211 and the lower surface 212, and a plurality of conductive pads 214 formed on the lower surface 212. Next, referring to FIG. 3B, a package 220 is disposed on the upper surface 211 of the carrier 210 and electrically connected to the carrier 210. The package 220 has a first surface 221, a second surface 222, and a plurality of conductive elements 223. The package 220 is electrically connected to the carrier 210 through the conductive elements 223. The package 220 may be a substrate type package or a leadframe type package, such as a BGA (Ball Grid Array) package or a TSOP (Thin Small Outline Package). In this embodiment, the package 220 has a structure of TSOP. The conductive elements 223 may be outer leads of a leadframe. Next, referring to FIG. 3C, the chip 230 is disposed on the second surface 222 of the package 220. In this embodiment, the chip 230 is adhered to the second surface 222 of the package 220 through an adhesive. The chip 230 has an active surface 231 and a plurality of bonding pads 232 on the active surface 231. The active surface 231 of the chip 230 faces to the carrier 210. The bonding pads 232 are corresponding to the opening 213 of the carrier 210. Next, referring to FIG. 3D, the bonding wires 240 are formed to connect the bonding pads 232 of the chip 230 and the conductive pads 214 on the lower surface 212 of the carrier 210, for electrically connecting the chip 230 and the carrier 210. Thereafter, please refer to FIG. 3E. A molding compound 250 is further formed to seal the package 220, the chip 230, and the bonding wires 240. Finally, a plurality of solder balls 260 are disposed on the lower surface 212 of the carrier 210, to form the semiconductor package 200 as shown in FIG. 2. In this embodiment, a plurality of solder ball pads 215 are formed on the lower surface 212 of the carrier 210 for bonding the solder balls 260.

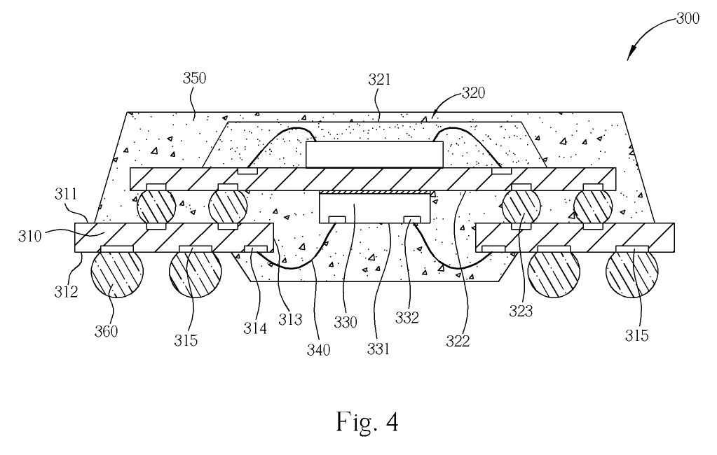

Please refer to FIG. 4, showing a semiconductor package 300 in the second embodiment according to the present invention, which comprises a carrier 310, a package 320, a chip 330, and a plurality of bonding wires 340. The carrier 310 has an upper surface 311, a lower surface 312, an opening 313 penetrating the upper surface 311 and the lower surface 312, and a plurality of conductive pads 314 disposed on the lower surface 312. The package 320 is disposed on the upper surface 311 of the carrier 310. The package 320 has a first surface 321, a second surface 322, and a plurality of conductive elements 223. The package 320 is electrically connected to the carrier 310 through the conductive elements 323. The package 320 may be a substrate type package or a leadframe type package, such as a BGA (Ball Grid Array) package or a TSOP (Thin Small Outline Package). In this embodiment, the package 320 has a structure of BGA (Ball Grid Array). The conductive elements 323 are solder balls. The chip 330 is disposed on the second surface 322 of the package 320. The chip 330 may be adhered to the second surface 322 of the package 320 through an adhesive. The chip 330 has an active surface 331 and a plurality of bonding pads 332 on the active surface 331. The active surface 331 of the chip 330 faces to the carrier 310. The bonding pads 332 are corresponding to the opening 313 of the carrier 310. The bonding wires 340 connect the bonding pads 332 of the chip 330 and the conductive pads 314 on the lower surface 312 of the carrier 310, for electrically connecting the chip 330 and the carrier 310. The semiconductor package 300 may further comprise a molding compound 350 sealing the package 320, the chip 330, and the bonding wires 340 and a plurality of solder balls 360 disposed on the lower surface 312 of the carrier 310. In this embodiment, a plurality of solder ball pads 315 are formed on the lower surface 312 of the carrier 310 for bonding the solder balls 360.

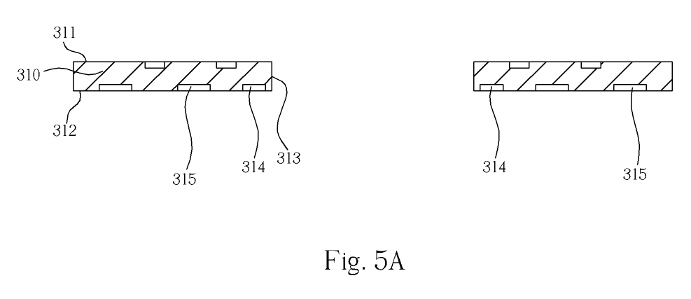

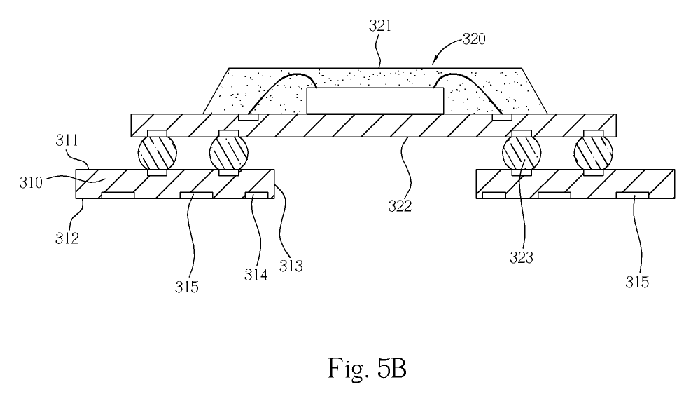

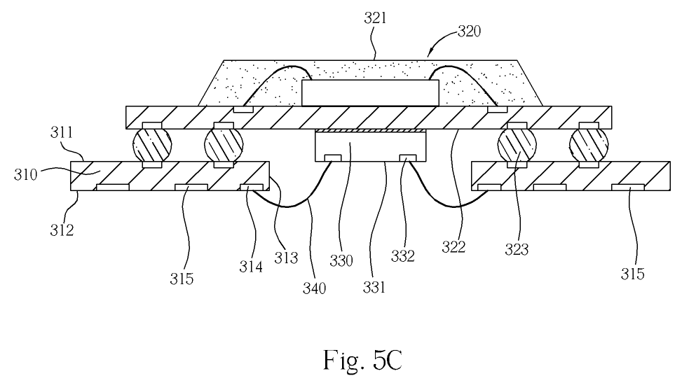

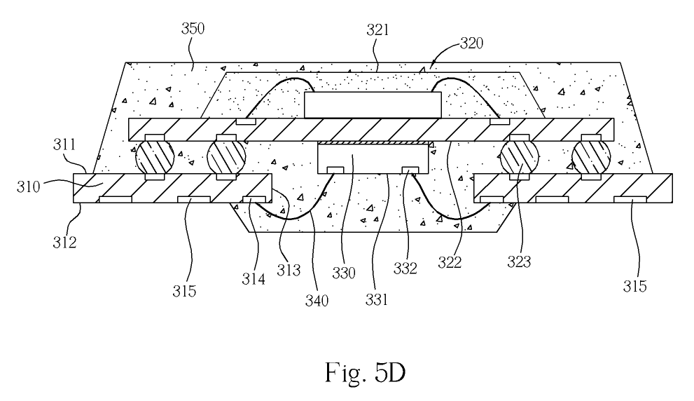

Please refer to FIGS. 5A to 5D illustrating the manufacturing process for the semiconductor package 300. First, referring to FIG. 5A, a carrier 310 is provided. The carrier 310 has an upper surface 311, a lower surface 312, an opening 313 penetrating the upper surface 311 and the lower surface 312, and a plurality of conductive pads 314 formed on the lower surface 312. Next, referring to FIG. 5B, a package 320 is disposed on the upper surface 311 of the carrier 310. The package 320 has a first surface 321, a second surface 322, and a plurality of conductive elements 323. The package 320 is electrically connected to the carrier 310 through the conductive elements 323. The package 320 may be a substrate type package or a leadframe type package, such as a BGA (Ball Grid Array) package or a TSOP (Thin Small Outline Package). In this embodiment, the package 320 has a structure of BGA. The conductive elements 323 are solder balls. Next, referring to FIG. 5C, the chip 330 is disposed on the second surface 322 of the package 320. The chip 330 may be adhered to the second surface 322 of the package 320 through an adhesive. The chip 330 has an active surface 331 and a plurality of bonding pads 332 on the active surface 331. The active surface 331 of the chip 330 faces to the carrier 310. The bonding pads 332 are corresponding to the opening 313 of the carrier 310. A plurality of bonding wires 340 connect the bonding pads 332 of the chip 330 and the conductive pads 314 on the lower surface 312 of the carrier 310, for electrically connecting the carrier 310 and the chip 330. Thereafter, please refer to FIG. 5D. A molding compound 350 is further formed to seal the package 320, the chip 330, and the bonding wires 340. Finally, a plurality of solder balls 360 are disposed on the lower surface 312 of the carrier 310, to form the semiconductor package 300 as shown in FIG. 4. In this embodiment, a plurality of solder ball pads 315 are formed on the lower surface 312 of the carrier 310 for bonding the solder balls 360.

Those skilled in the art will readily observe that numerous modifications and alterations of the device and method may be made while retaining the teachings of the invention.

What is claimed is:

1. A semiconductor package comprising:
a carrier comprising an upper surface, a lower surface, an opening penetrating the upper surface and the lower surface, and a plurality of conductive pads disposed on the lower surface;
a package disposed on the upper surface of the carrier, the package comprising a first surface, a second surface, and a plurality of conductive elements electrically connecting the package to the carrier;
a chip disposed on the second surface of the package, the chip comprising an active surface facing to the carrier and a plurality of bonding pads corresponding to the opening of the carrier; and
a plurality of bonding wires connecting the bonding pads and the conductive pads.

2. The semiconductor package as claimed in claim 1, wherein the package comprises a structure of a substrate type package or a structure of a leadframe type package.

3. The semiconductor package as claimed in claim 1, wherein the conductive elements comprise solder balls or outer leads.

4. The semiconductor package as claimed in claim 1, further comprising a molding compound sealing the package, the chip, and the bonding wires.

5. The semiconductor package as claimed in claim 1, further comprising a plurality of solder balls disposed on the lower surface of the carrier.

6. The semiconductor package as claimed in claim 1, wherein the chip is adhered to the second surface of the package through an adhesive.
